(19) United States
(12) Patent Application Publication
(10) Pub. No.: US 2007/0152683 A1
(43) Pub. Date: Jul. 5, 2007

(54) Electronic device for analysis of a body fluid

(76) Inventors: Karl Werner, Wiesloch (DE); Nader Afshar, Fishers, IN (US); Morris Young, Indianapolis, IL (US); Paul Galley, Cumberland, IN (US); Alan Greenburg, Indianapolis, IN (US)

Correspondence Address: BARNES & THORNBURG LLP, 11 SOUTH MERIDAN STREET, INDIANAPOLIS, IN, 46204, US

(21) Appl. No.: 11/322,542

(22) Filed: Dec. 30, 2005

(51) Int. Cl. G01R 27/08

(52) U.S. Cl. 324/693

(57) ABSTRACT

An electronic device for analysis of a body fluid comprises a housing defining an opening therein, a measuring facility and at least one electrical circuit arranged inside the housing, and a multi-wire connector carried by the housing. The measuring facility is configured to receive a test element therein via the opening and to produce measuring values relating to a sample of the body fluid received on the test element. The at least one electrical circuit is configured to process the measuring values to yield analytical data corresponding to a component of the sample of the body fluid. The multi-wire connector has at least one wire defining a voltage supply input to the electronic device, and is configured to be connected to a mating connector of an external electronic device with the at least one wire configured to receive a supply voltage from the external electronic device.

### FIELD OF THE INVENTION

The present invention relates to electronic devices for analyzing body fluids.

### BACKGROUND AND SUMMARY

For qualitative and quantitative analysis of components of a liquid sample, in particular of a body fluid from humans or animals, test methods working with test elements are used extensively. The test elements generally contain reagents. In order to perform a reaction, the test element is contacted with the liquid sample. The reaction between the liquid sample and the reagent leads to a change in the test element that is characteristic of the analysis, and this change is analyzed using a suitable analytical device. Typically, the analytical device is suitable for analysis of a specific type of test element from a specific manufacturer. The test elements and the analytical device are mutually adapted components and, in combination, are called an analytical system.

In many cases, there is a need for regular monitoring of certain analytic blood values. This applies in particular to diabetics who should self-monitor their blood glucose levels frequently in order to maintain these levels within certain nominal limits (ideally, at all times) by suitably adapting their insulin intake via injection or other means. The testing of blood coagulation parameters by patient blood coagulation self-monitoring is also quite common, as is self-monitoring of blood cholesterol levels.

A blood glucose measuring device is a measuring device that can be used for qualitative or quantitative determination of the blood glucose content. For this purpose, it is customary to generate a puncture wound in a body, draw a drop of blood, apply the drop of blood to a test element, and use the test element and the blood glucose measuring device to determine the blood glucose content or concentration of the drop. However, it is also conceivable to measure the blood glucose by means of a continuous measurement, for example with sensors introduced into the body or by a measurement through the skin.

In the area of so-called “home monitoring”, i.e. where medical laymen perform simple blood analyses, and, in particular, in the periodical drawing of blood several times daily by diabetics for monitoring of their blood glucose concentration, it is important to have a blood glucose measuring device that is easy and reliable to operate and to have an informative and reliable determination and display of the measuring results.

Conventional analytical devices are so-called stand-alone measuring devices. These devices operate autonomously, self-supporting, and independently. Accordingly, they comprise a display, a measuring facility, a power supply, and a complete user interface that can, for example, comprise a keyboard, a display, a triggering facility or user guidance. The application purpose and properties of devices of this type are fixed with the exception of occasional adaptation of their firmware.

The present invention may comprise one or more of the features recited in the attached claims, and/or one or more of the following features and combinations thereof. In one illustrative embodiment, an electronic device for analysis of a body fluid may comprise a housing defining a first opening therein, a measuring facility arranged inside the housing and configured to receive a test element therein via the first opening, at least one electrical circuit arranged inside the housing and a multi-wire connector carried by the housing and electrically connected to the at least one electrical circuit. The measuring facility may be configured to produce measuring values relating to a sample of the body fluid received on the test element. The at least one electrical circuit may be configured to process the measuring values to yield analytical data corresponding to a component of the sample of the body fluid. The multi-wire connector may have at least one wire defining a voltage supply input to the electronic device. The multi-wire connector may be configured to be connected to a mating connector of an external electronic device with the at least one wire configured to receive a supply voltage from the external electronic device.

The measuring facility may comprise at least one electrode configured to produce the measuring values based on an electrochemical reaction of the body fluid with the test element. Alternatively, the measuring facility may comprise an optical detector configured to produce the measuring values based on at least one optical property resulting from a reaction of the body fluid with the test element. In either case, the measuring facility may be configured to receive therein the test element provided in the form of a test strip having the sample of the body fluid deposited thereon. Alternatively, the housing may define a second opening extending into the measuring facility and being aligned with the test element when the test element is received in the first opening. In this embodiment, the sample of the body fluid may be received on the test element via the second opening in the housing. The multi-wire connector may be one of a universal serial bus connector and a firewire interface. The electronic device does not include a display, nor does it include a user interface for providing user input of instructions or information to the electronic device. The component of the sample of the body fluid may be one of blood glucose, cholesterol and a blood coagulation parameter.

In another illustrative embodiment, an electronic device for analysis of a body fluid may comprise a housing defining a first opening therein, a measuring facility arranged inside the housing and configured to receive a test element therein via the first opening, at least one electrical circuit arranged inside the housing and a multi-wire connector carried by the housing and electrically connected to the at least one electrical circuit. The measuring facility may be configured to produce measuring values relating to a sample of the body fluid received on the test element. The at least one electrical circuit may be configured to process the measuring values to yield analytical data corresponding to a component of the sample of the body fluid. The multi-wire connector may have at least one wire defining a control input to the electronic device and be configured to be connected to a mating connector of an external electronic device with the at least one wire configured to receive control signals from the external electronic device for operating the electronic device.

The measuring facility may comprise at least one electrode configured to produce the measuring values based on an electro-chemical reaction of the body fluid with the test element. Alternatively, the measuring facility may comprise an optical detector configured to produce the measuring values based on at least one optical property resulting from a reaction of the body fluid with the test element. In either case, the measuring facility may be configured to receive therein the test element provided in the form of a test strip having the sample of the body fluid deposited thereon. Alternatively, the housing may define a second opening extending into the measuring facility and aligned with the test element when the test element is received in the first opening. In this embodiment, the sample of the body fluid may be received on the test element via the second opening in the housing. The multi-wire connector may be one of a universal serial bus connector and a firewire interface. The multi-wire connector may be mounted to, and extend from, the housing. The electronic device does not include a display, nor does it include a user interface for providing user input of instructions or information to the electronic device. The component of the sample of the body fluid may be one of blood glucose, cholesterol and a blood coagulation parameter.

In yet another illustrative embodiment, an electronic device for analysis of a body fluid may comprise a housing defining a first opening therein, a measuring facility arranged inside the housing and configured to receive a test element therein via the first opening, at least one electrical circuit arranged inside the housing and a universal serial bus (USB) interface carried by the housing and electrically connected to the at least one electrical circuit. The measuring facility, the at least one electrical circuit and the USB interface may together form a USB device. The measuring facility may be configured to produce measuring values relating to a sample of the body fluid received on the test element. The at least one electrical circuit may be configured to process the measuring values to yield analytical data corresponding to a component of the sample of the body fluid.

The USB interface may be configured to be electrically connected to a mating USB interface of either of a USB host and a USB hub. The USB interface may be a first USB connector configured to be electrically connected to a second USB connector of one of a USB host and a USB hub. The USB host may be one of a personal computer, a laptop computer and a notebook computer. Alternatively, the USB interface may be a wireless USB interface. In any case, the electronic device does not include a display, nor does it include a user interface for providing user input of instructions or information to the electronic device. The component of the sample of the body fluid may be one of blood glucose, cholesterol and a blood coagulation parameter. The measuring facility may comprise at least one electrode configured to produce the measuring values based on an electrochemical reaction of the body fluid with the test element. Alternatively, the measuring facility may comprise an optical detector configured to produce the measuring values based on at least one optical property resulting from a reaction of the body fluid with the test element.

In a further illustrative embodiment, an electronic device for analysis of a body fluid may comprise a housing defining a first opening therein, a measuring facility arranged inside the housing and configured to receive a test element therein via the first opening, at least one electrical circuit arranged inside the housing, a memory unit arranged inside the housing and having stored therein instructions for operating the electronic device and an electrical interface electrically connected to the at least one electrical circuit. The measuring facility may be configured to produce measuring values relating to a sample of the body fluid received on the test element. The at least one electrical circuit may be configured to process the measuring values to yield analytical data corresponding to a component of the sample of the body fluid. The electrical interface may be configured for communication with an electrical interface of an external electronic device configured to execute the instructions stored in the memory unit to thereby control the electronic device.

The electronic device does not include a display, nor does it include a user interface for providing user input of instructions or information to the electronic device. The component of the sample of the body fluid may be one of blood glucose, cholesterol and a blood coagulation parameter. The measuring facility may comprise at least one electrode configured to produce the measuring values based on an electrochemical reaction of the body fluid with the test element. Alternatively, the measuring facility may comprise an optical detector configured to produce the measuring values based on at least one optical property resulting from a reaction of the body fluid with the test element.

In still another illustrative embodiment, an electronic device for analysis of a body fluid may comprise a housing defining an opening therein, a measuring facility arranged inside the housing and configured to receive a test element therein via the opening, at least one electrical circuit arranged inside the housing and an interface configured to transfer information between the electronic device and an external electronic device. The measuring facility may be configured to produce measuring values relating to a sample of the body fluid received on the test element. The at least one electrical circuit may be configured to process the measuring values to yield analytical data corresponding to a component of the sample of the body fluid. The electronic device does not include a display.

The electronic device does not include a user interface for providing user input of instructions or information to the electronic device. The component of the sample of the body fluid may be one of blood glucose, cholesterol and a blood coagulation parameter. The measuring facility may comprise at least one electrode configured to produce the measuring values based on an electrochemical reaction of the body fluid with the test element. Alternatively, the measuring facility may comprise an optical detector configured to produce the measuring values based on at least one optical property resulting from a reaction of the body fluid with the test element.

In still a further illustrative embodiment, an electronic device for analysis of a body fluid may comprise a housing defining an opening therein, a measuring facility arranged inside the housing and configured to receive a test element therein via the opening, at least one electrical circuit arranged inside the housing and an electrical interface configured to transfer information between the electronic device and an external electronic device. The measuring facility may be configured to produce measuring values relating to a sample of the body fluid received on the test element. The at least one electrical circuit may be configured to process the measuring values to yield analytical data corresponding to a component of the sample of the body fluid. The electronic device does not include a user interface for providing user input of instructions or information to the electronic device.

The electronic device does not include display. The component of the sample of the body fluid may be one of blood glucose, cholesterol and a blood coagulation parameter. The measuring facility may comprise at least one electrode configured to produce the measuring values based on an electrochemical reaction of the body fluid with the test element. Alternatively, the measuring facility may comprise an optical detector configured to produce the measuring values based on at least one optical property resulting from a reaction of the body fluid with the test element.

In yet another illustrative embodiment, a system for analyzing a body fluid may comprise a body fluid analysis device, an electronic device and an electrical interface configured to transfer information between the body fluid analysis device and the electronic device. The body fluid analysis device may comprising a measuring facility configured to receive a test element therein and configured to produce measuring values relating to a sample of the body fluid received on the test element, and at least one electrical circuit configured to process the measuring values to yield analytical data corresponding to a component of the sample of the body fluid. The electronic device may comprise a processor electrically connected to a display unit. The processor may be configured to receive the analytical data from the body fluid analysis device and to control the display unit to display the analytical data.

The electronic device may include a memory having stored therein instructions for operating the body fluid analysis device. The processor of the electronic device may be configured to execute the instructions stored in the memory to control operation of the body fluid analysis device. Alternatively, the body fluid analysis device may include a memory having stored therein instructions for operating the body fluid analysis device. In this embodiment, the processor of the electronic device may be configured to receive the instructions from the memory of the body fluid analysis device and to execute the instructions to control operation of the body fluid analysis device.

The electrical interface may comprise a first multi-wire connector associated with the body fluid analysis device, and a second multi-wire connector associated with the electronic device. The processor of the electronic device may be configured to automatically control operation of the body fluid analysis device, receive the analytical data from the body fluid analysis device and control the display unit to display the analytical data, upon detection of an electrical connection between the first and second multi-wire connectors. The electrical interface may comprise a universal serial bus interface. In this embodiment, the body fluid analysis device is a USB device and the electronic device is a USB host. The body fluid analysis device does not include a display, nor does it include a user interface for providing user input of instructions or information to the electronic device. The component of the sample of the body fluid may be one of blood glucose, cholesterol and a blood coagulation parameter. The electronic device may be one of a personal computer, a laptop computer and a notebook computer.

### BRIEF DESCRIPTION OF THE DRAWINGS

FIG. 1 is a diagram of one illustrative embodiment of a system for analyzing a body fluid.

FIG. 2 is a diagram of one illustrative embodiment of the body fluid analysis device illustrated in FIG. 1.

FIG. 3 is a schematic diagram of one illustrative embodiment of the body fluid analysis device illustrated in FIG. 2.

### DESCRIPTION OF THE ILLUSTRATIVE EMBODIMENTS

For the purposes of promoting an understanding of the principles of the invention, reference will now be made to a number of illustrative embodiments shown in the attached drawings and specific language will be used to describe the same.

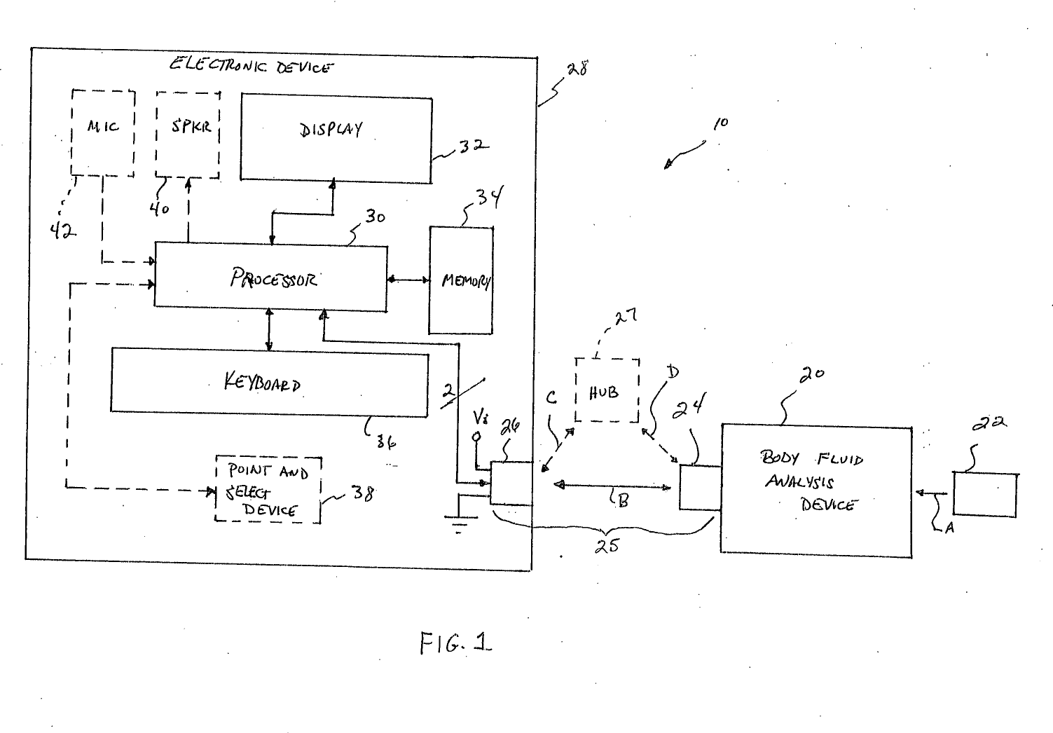

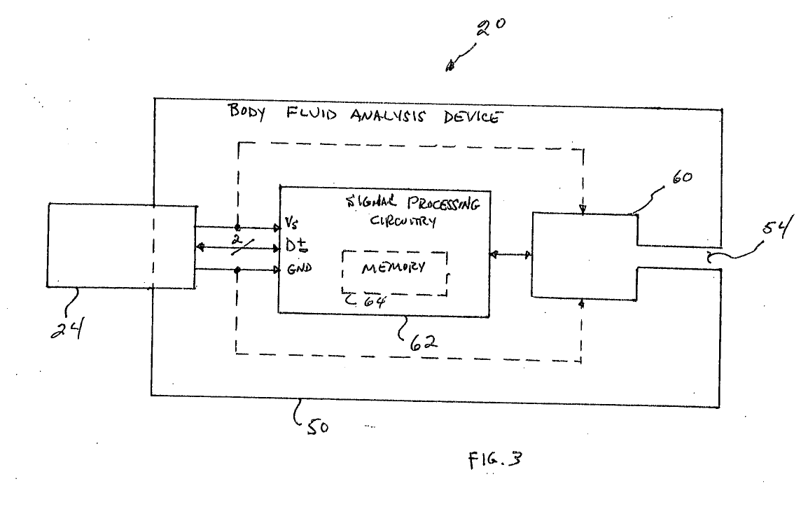

Referring now to FIG. 1, a diagram of one illustrative embodiment of a system 10 for analyzing a body fluid is shown. In the illustrated embodiment, the system 10 includes a body fluid analysis device 20 that is configured to be electrically connected to an electrical device 28 via an electrical interface indicated generally at 25. The body fluid analysis device 20 includes a measuring facility that is configured to receive therein a test element 22, e.g., as illustrated by the directional arrow “A,” on which a sample of the body fluid is received. As will be described in greater detail hereinafter with reference to FIG. 3, the measuring facility is generally configured to produce measuring values relating to the sample of body fluid received on the test element 22. The body fluid analysis device 20 further includes at least one electrical circuit that is configured to process the measuring values to yield analytical data corresponding to a component of the sample of the body fluid. The body fluid analysis device 20 may generally be any electronic device configured to analyze a sample of a body fluid to determine at least one component thereof. Example implementations of the body fluid analysis device 20 include, but should not be limited to, a blood glucose measuring device, a body fluid cholesterol measuring device and a blood coagulation parameter measuring device.

The electronic device 28 includes a conventional processor 30 that is electrically connected to a conventional display device or unit 32, a conventional memory device or unit 34, and a conventional keyboard or keypad 36. The electronic device 28 may further include a conventional point and select device 38, one or more conventional speakers 40 and/or a conventional microphone 42, each electrically connected to the processor 30 as shown by dashed-line representation in FIG. 1. The electronic device 28 may generally be any processor-based electronic device, portable or otherwise, that carries its own source of electrical power, e.g., a dedicated voltage source (not shown), and/or that includes a hardwire interface (not shown) configured to be electrically connected to a suitable source of electrical power. Example implementations of the electronic device 28 include, but are not limited to, a conventional personal computer (PC), a conventional laptop or notebook computer, a conventional hand-held electronic device such as a personal data assistant (PDA), or the like.

With any implementation of the body fluid analysis device 20 and electronic device 28, an electrical interface 25 is provided to electrically connect the devices 20 and 25. Generally, the electrical interface 25 is a multi-wire, hardwire interface, and in this regard the body fluid analysis device 20 includes an electrical connector 24 configured to be electrically connected to another electrical connector 26 of the electronic device 28. In the illustrated embodiment, the electrical connectors 24 and 26 are provided in the form of conventional universal serial bus (USB) connectors, although the electrical interface 25 and electrical connectors 24, 26 may alternatively be configured as a conventional wire-based serial interface, parallel interface, firewire interface or other conventional wire-based electrical interface.

In the specific exemplary embodiment illustrated in FIG. 1, the electrical connector 24 of the body fluid analysis device 20 is a male, Type-A USB connector and the electrical connector 26 of the electronic device 28 is a corresponding Type-A USB port. In any case, with the electrical interface 25 implemented in the form of a USB interface, the electronic device 28 acts as a “USB host,” and the body fluid analysis device 20 as a “USB device,” meaning that the electronic device 28 controls operation of the body fluid analysis device 20 in accordance with a conventional USB communications protocol carried out over the USB interface 25. The electronic device 28 automatically detects the body fluid analysis device 20 when electrical connection is made between the electrical connectors 24 and 26, and if the device 20 has not been connected to the device 28 before, the operating system of the device 28 loads an appropriate driver that is either already resident on the device 28 or is obtained from an external source such as from the device 20 itself. In any case, when the appropriate device driver is loaded onto the electronic device 28, the device 28 then activates the device 20, establishes communication with the device 20 according to a conventional USB communications protocol, and thereafter controls operation of the device 20 via conventional a USB communications protocol. Illustratively, USB communications may be carried according to a conventional USB version 2.0 standard, although other conventional USB protocols may be used. Generally, USB devices are “hot-swappable”, meaning that they can be connected and disconnected at any time without having to restart or reboot either device 20 or 28.

In the illustrated embodiment, electrical connection is made between the body fluid analysis device 20 and the electronic device 28 by simply inserting male, Type-A USB connector 24 into the Type-A USB port 26 as illustrated by the directional arrow “B.” Alternatively, a conventional USB hub 27 may be interposed between the connectors 24 and 26 to allow the electronic device 28 to act as a USB host to multiple USB devices via a the single USB port 26. In this case, the hub 27 includes an electrical connector configured to be electrically connected to the USB port 26 of the electronic device 28, typically via a hardwire cable, as illustrated by the directional arrow “C,” and also includes an electrical connector configured to be electrically connected to the electrical connector 24 of the body fluid analysis device 20, as illustrated by the direction arrow “D,” which may or may not be accomplished via a hardwire cable. Generally, when hardwire cabling is used in a USB interface, the connector/port combination on the host-side is typically a conventional Type-A USB connector/port combination and the connector/port combination on the device-side is a conventional Type-B USB connector. Thus, in cases where a hub 27 is used, the electrical connector on the hub 27 to which the USB port 26 of the electronic device 28 is connected will typically be a conventional Type-B USB connector or port. Likewise, if a hardwire cable is used to connect the device 20 to the hub 27, the electrical connector on the hub 27 to which the USB connector 24 of the device 20 connects will typically be a conventional Type-A port and the electrical connector 24 on the body fluid analysis device 20 will typically be a conventional Type-B USB connector or port.

In the illustrated embodiment, the USB connectors 24 and 26 are implemented as “standard” USB connectors, wherein a standard Type-A or Type-B USB connector or port has four connections; one being a voltage bus, one being a ground reference and two forming a pair of differential data connections, D+ and D−, for conducting communications according to a conventional USB communications protocol. Thus, the connectors 24 and 26 each have a voltage bus connection, a ground connection and two data transfer connections. Alternatively, the USB connectors 24 and 26 may be provided in the form of “mini” USB connectors, wherein a mini-USB connector or port has five connections; the four previously described for a standard USB connector and an additional “ID” connection. In either case, the voltage bus of the connector 26 carried by the electronic device 28 is connected to a supply voltage, V_{S}, internal to the electronic device 28. The body fluid analysis device 20, in the illustrated embodiment, does not have an internal voltage source or other source of electrical power, and instead the supply voltage, V_{S}, provides the sole source of electrical power for the body fluid analysis device 20 when electrical connection is made between the devices 20 and 28. In another alternative embodiment, the USB connectors 24 and 26 may be wireless USB connectors, and in this embodiment the body fluid analysis device 20 will require a dedicated voltage source such as one or more conventional batteries.

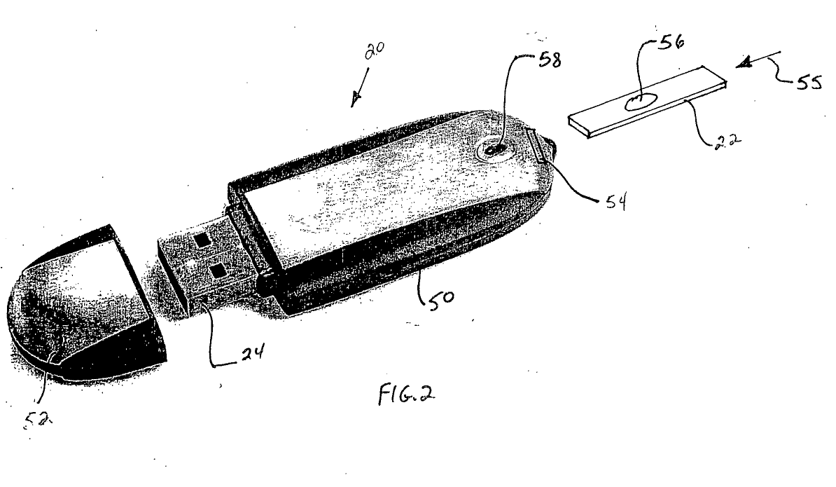

Referring now to FIG. 2, a diagram of one illustrative embodiment of the body fluid analysis device 20 of FIG. 1 is shown. The device 20 is generally an electronic device configured to analyze a body fluid, and may illustratively be implemented, as described hereinabove, in the form of a portable, patient-operable blood glucose measuring device for self-monitoring of blood glucose values by the patient. In the illustrated embodiment, the device 20 comprises a housing 50 provided approximately in the design of a conventional USB stick and has a standardized, wire-based USB connector 24 that is provided in the form of a male, Type-A USB connector mounted to and extending from the housing 50 of the device 20. A conventional protective cap 52 may be provided to protect the electrical connector 24 from damage during periods of non-use.

One or more components of the body fluid are determined by analyzing a sample of a body fluid of the patient, e.g., blood, which is applied to a test field 56 of the test element 22. The test element 22 is inserted through an opening 54 in the housing 50 that leads to a measuring facility arranged in the housing 50, as indicated by the directional arrow 55. In one exemplary embodiment, the body fluid is deposited or otherwise received on the test field 56 of the test element 22, and the test element 22 is then inserted, via the opening 54, into the measuring facility arranged in the housing 50. Alternatively, the housing 50 may define a second opening 58 therein that also leads to the measuring facility and that generally aligns with the test field 56 when the test element 22 is inserted, via the opening 54, into the measuring facility arranged in the housing 22. In this embodiment, the test element 22 is first inserted into the measuring facility as just described, and the body fluid is then deposited or otherwise received on the test field 56 via the opening 58.

Numerous different types of test elements 22 are known which differ from each other by their measuring principle and/or reagents that are used, as well as by their structure. With regard to the measuring principle carried out in the measuring facility, any conventional body fluid analytical technique may be used. As one example, optical analytical systems are generally known and commonly used to analyze body fluids, e.g., blood. In these conventional systems, the sample of the body fluid reacting with the reagents contained in the test element 22 produces an optically detectable change that can be measured visually and/or via an optical detection system. Examples of conventional optical analytical systems include, but are not limited to, colorimetric analytical systems, wherein the body fluid sample reacting with the reagents contained in the test element 22 leads to a color change that can be measured visually or by means of a conventional photometric measuring facility, reflectance-type analytical systems wherein the body fluid sample reacting with the reagents contained in the test element 22 leads to changes in the reflectance properties of the sample that can be measured by a conventional reflectance measuring facility, and fluorescence or phosphorescence-type analytical systems wherein the body fluid sample reacting with the reagents contained in the test element is illuminated which leads to a resulting visible emission that can be measured by a suitable conventional fluorescence or phosphorescence measuring facility. Moreover, electrochemical analytical systems are also known, and in such systems the body fluid sample reacting with the reagents of the test element 22 leads to an electrically detectable change (e.g., of an electrical voltage or an electrical current) that is measured with appropriate conventional measuring electronics including, for example, one or more conductive electrodes. Analytical systems of this type are generally called amperometric systems. The measuring facility contained in the housing 50 may, for example, be a colorimetric or electrochemical measuring facility, and in any case the measuring facility is configured to produce measuring values relating to the sample of the body fluid received on the test element 22.

Referring now to FIG. 3, a schematic diagram of one illustrative embodiment of the body fluid analysis device 20 of FIG. 2 is shown. In the illustrated embodiment, which is generally representative of a cross-sectional view along a longitudinal axis of the device 20, the opening or slit 54 in the housing 50 is shown leading to a measuring facility 60 which may be implemented in any of the forms described hereinabove. The measuring facility 60 is electrically connected to conventional signal processing circuitry 62 which is, in turn, electrically connected to the electrical connector 24. The voltage supply line and the ground reference line of the connector 24 are electrically connected to supply voltage and ground reference inputs, V_{S} and GND respectively, of the signal processing circuitry 62. The communication lines, e.g., D+ and D−, of the electrical connector 24 are likewise electrically connected to the signal processing circuitry. In embodiments where the measuring facility 60 includes one or more electrical components requiring a supply voltage for operation, the voltage supply line and the ground reference line of the electrical connector 24 are also electrically connected to the measuring facility as shown by dashed line representation in FIG. 3. As discussed hereinabove, the body fluid analysis device 20 does not include a voltage supply, and any electrical power required for operation of the device 20 is supplied by the electronic device 28 via the electrical interface 25. In particular, the multi-wire electrical connector 24 has at least one wire that defines a voltage supply input to the body fluid analysis device 20, and the electrical connector 24 configured to be connected to a mating connector 26 of the external electronic device 28 with the at least one wire making electrical contact with the voltage supply line, V_{S}, of the electrical connector 26 so as to receive the supply voltage from the electronic device 28.

The signal processing circuitry 62 includes at least one electrical circuit that is arranged inside the housing 50 and configured to process the measuring values produced by the measuring facility 60 in a conventional manner to yield analytical data corresponding to a component, e.g., blood glucose concentration, of the sample of the body fluid received on the test element 22. The analytical data is then provided by the signal processing circuitry 62 to the electronic device 28 via the electrical interface 25 as shown and described with respect to FIG. 1. In embodiments of the system 10 wherein the electrical interface 25 is a USB interface as described in detail hereinabove, the signal processing circuitry 62 will typically, although not necessarily, include a conventional processor circuit, such as a microprocessor. Such a processor is configured to process the measuring values produced by the measuring facility 60 to yield the analytical data, to also communicate with the processor 30 of the electronic device 28 via the USB interface 25 in accordance with a conventional USB communications protocol, and to act upon instructions received from the processor 30. In other embodiments, the signal processing circuitry 62 may or may not include a conventional processor circuit, but will in any case include appropriate circuitry configured to process the measuring values produced by the measuring facility 60 and to act upon instructions provided by the processor 30 of the electronic device 28. In any case, the multi-wire electrical connector 24 carried by the housing 50 and electrically connected to the signal processing circuitry 62, has at least one wire (two shown in FIGS. 1 and 3) defining a control input to the body fluid analysis device 20. When the multi-wire electrical connector 24 is connected to the mating connector 26 of the electronic device 28 to establish the electrical interface 25, the control input to the body fluid analysis device 20 is electrically connected to the processor 30 and may receive control signals from the processor 30 of the electronic device 28 for operating the body fluid analysis device 20.

The signal processing circuitry 62 may, in some embodiments, include a memory unit 62 arranged inside the housing 50, and the memory unit 62 may have stored therein instructions for operating the body fluid analysis device 20. In such embodiments, the signal processing circuitry 62 may include a processor configured to execute the instructions stored in the memory unit 62 to operate the body fluid analysis device as described herein. Alternatively, the processor 30 of the electronic device 28 may, after the electrical interface 25 is established between the devices 20 and 28, retrieve the instructions from the memory unit 62 and execute the instructions to operate and control the body fluid analysis device 20 as described herein.

With the system 10 illustrated and described herein, data may generally be provided from the body fluid analysis device 20 to the electronic device 28 via the electrical interface 25, and the processor 30 of the electronic device 28 may be configured to process such data and control the display unit 32 to display operating parameters and/or analytical data provided by the body fluid analysis device 20. Likewise, data in the form of instructions or control signals may be provided by the processor 30 of the electronic device 28 to the body fluid analysis device 20 via the electrical interface 25 such that the processor 30 of the electronic device 28 can control operation of the body fluid analysis device 20, for example in order to configure the body fluid analysis device 20 and/or to trigger certain actions of the body fluid analysis device 20, in particular the carrying out of an analysis of a test element 22 that is inserted into the device 20. In this manner, the body fluid analysis device 20 can be partially or fully controlled and operated by the processor 30 of the electronic device 28.

In the exemplary embodiments illustrated and described herein, it will be noted that the body fluid analysis device 20 does not include an intrinsic user interface for providing user input of instructions or information to the body fluid analysis device 20 such as for operating the device 20. Rather, operation of the body fluid analysis device 20 in carrying out an analysis on a test element 22 that is inserted into the device 20 is controlled exclusively by the electronic device 28. For example, the processor 30 of the electronic device 28 may illustratively be programmed to recognize, after the electronic device 28 is electrically connected to the body fluid analysis device 20 via the electrical interface 25, when a test element 22 is being inserted into the device 20, and to then automatically command start-up of the measurement and the display of the measuring result, for example, on the display unit 32 of the computer without this requiring an input of the user on any user interface. In such embodiments, the system 10 may dispense altogether with any type of user interface for controlling and operating the device 20. In alternative embodiments, any user input that may be required or that may be useful to the operation of the device 20 may be entered by the user via the keyboard or keypad 36 and/or point and select device 38, or alternatively via a microphone 42 in embodiments of the electronic device 28 that are configured to receive and act upon voice commands from the user.

In the exemplary embodiments illustrated and described herein, it will be further be noted that the body fluid analysis device 20 does not include an intrinsic user interface for displaying or otherwise conveying analytical data determined by the device 20. Rather, display or other conveyance of analytical data determined by the body fluid analysis device 20 is carried out exclusively by the electronic device 28. For example, the processor 30 of the electronic device 28 may illustratively be programmed to receive via the electrical interface 25 analytical data from the body fluid analysis device 20 resulting from analysis of a sample of body fluid received on a test element 22, and to present this analytical data to the patient using only data presenting components of the electronic device 28. In one embodiment, for example, the processor 30 may control the display unit 32 to display thereon the analytical data in textual and/or graphic form. Alternatively or additionally, the processor 30 may control the speaker 40, in embodiments of the electronic device 28 that include a speaker 40, to audibly convey the analytical data to the patient.

The electronic device 28 to which the body fluid analysis device 20 is connected may also be used also for documenting other self-monitoring data of the patient which the electronic device 28 may import from the body fluid analysis device 20 and/or which may be entered into the electronic device 28 by the patient. Self-monitoring data of this type can be relevant, for example, for the monitoring, diagnosis or therapy of the blood glucose disease, such as type, time, and quantity of meals ingested, physical activities, insulin quantities administered and/or other relevant events.

In order for the history of such data to be available to the user of the body fluid analysis device 20, particularly when the device 20 may be connectable to multiple different electronic devices, it may be desirable to include the memory unit 64 in signal processing circuitry 62. In such cases, the processor of any electronic device that the body fluid analysis device 20 may electrically connect to can then be configured to store analytical data, calibration data and/or other data (e.g., date and time of day of the measurement) in the memory unit 64 of the body fluid analysis device 20. This allows the user to connect the body fluid analysis device 20 to more than one electronic device for the purpose of importing, displaying and/or analyzing any one or more of the stored analytical data values.

As described hereinabove, the processor 30 of the electronic device 28 operates to automatically recognize the body fluid analysis device 20 when it is connected to the electronic device 28 via a USB interface 25. The processor 30 then loads the necessary pre-installed drivers and application programs for importing data from the device 20 and for controlling operation of the device 20 by the electronic device 28. In order to render the body fluid analysis device 20 universally operable, i.e., without pre-configuration of the corresponding electronic device 28, and thus provide for its use with any electronic device 28, the signal processing circuitry 62 if the device 20 may include the memory unit 62 having stored therein instructions in the form of software required for controlling operation of the device 20. In this embodiment, the processor 30 of any electronic device 28 to which the body fluid analysis device 20 is connected may be operable to import this software from the memory unit 64 and then execute the imported software to control operation of the device 20.

However, in other embodiments it may be desirable not to require any specific drivers and/or specific software for controlled operation of the body fluid analysis device 20, and for the analytical data determined by the device 20 to instead be imported from the device 20 by the electronic device 28 using standard software, for example a browser such as Windows Explorer, which may be previously installed on the electronic device 28, such as when the electronic device 28 is implemented in the form of a PC, laptop or notebook computer. In this case, the body fluid analysis device 20 can be operated universally by the majority of computers without any need for pre-configuration of the computer.

While the invention has been illustrated and described in detail in the foregoing drawings and description, the same is to be considered as illustrative and not restrictive in character, it being understood that only illustrative embodiments thereof have been shown and described and that all changes and modifications that come within the spirit of the invention are desired to be protected.

What is claimed is:

1. An electronic device for analysis of a body fluid comprising:
a housing defining a first opening therein,
a measuring facility arranged inside the housing and configured to receive a test element therein via the first opening, the measuring facility configured to produce measuring values relating to a sample of the body fluid received on the test element,
at least one electrical circuit arranged inside the housing and configured to process the measuring values to yield analytical data corresponding to a component of the sample of the body fluid, and
a multi-wire connector carried by the housing and electrically connected to the at least one electrical circuit, the multi-wire connector having at least one wire defining a voltage supply input to the electronic device, the multi-wire connector configured to be connected to a mating connector of an external electronic device with the at least one wire configured to receive a supply voltage from the external electronic device.

2. The electronic device of claim 1 wherein the measuring facility comprises at least one electrode configured to produce the measuring values based on an electrochemical reaction of the body fluid with the test element.

3. The electronic device of claim 1 wherein the measuring facility comprises an optical detector configured to produce the measuring values based on at least one optical property resulting from a reaction of the body fluid with the test element.

4. The electronic device of claim 1 wherein the measuring facility is configured to receive therein the test element provided in the form of a test strip having the sample of the body fluid deposited thereon.

5. The electronic device of claim 1 wherein the housing defines a second opening extending into the measuring facility and being aligned with the test element when the test element is received in the first opening
and wherein the sample of the body fluid is received on the test element via the second opening in the housing.

6. The electronic device of claim 1 wherein the multi-wire connector is one of a universal serial bus connector and a firewire interface.

7. The electronic device of claim 1 wherein the electronic device does not include a display.

8. The electronic device of claim 1 wherein the electronic device does not include a user interface for providing user input of instructions or information to the electronic device.

9. The electronic device of claim 1 wherein the component of the sample of the body fluid is one of blood glucose, cholesterol and a blood coagulation parameter.

10. An electronic device for analysis of a body fluid comprising:
a housing defining a first opening therein,
a measuring facility arranged inside the housing and configured to receive a test element therein via the first opening, the measuring facility configured to produce measuring values relating to a sample of the body fluid received on the test element,
at least one electrical circuit arranged inside the housing and configured to process the measuring values to yield analytical data corresponding to a component of the sample of the body fluid, and
a multi-wire connector carried by the housing and electrically connected to the at least one electrical circuit, the multi-wire connector having at least one wire defining a control input to the electronic device, the multi-wire connector configured to be connected to a mating connector of an external electronic device with the at least one wire configured to receive control signals from the external electronic device for operating the electronic device.

11. The electronic device of claim 10 wherein the measuring facility comprises at least one electrode configured to produce the measuring values based on an electrochemical reaction of the body fluid with the test element.

12. The electronic device of claim 10 wherein the measuring facility comprises an optical detector configured to produce the measuring values based on at least one optical property resulting from a reaction of the body fluid with the test element.

13. The electronic device of claim 10 wherein the measuring facility is configured to receive therein the test element provided in the form of a test strip having the sample of the body fluid deposited thereon.

14. The electronic device of claim 10 wherein the housing defines a second opening extending into the measuring facility and being aligned with the test element when the test element is received in the first opening
and wherein the sample of the body fluid is received on the test element via the second opening in the housing.

15. The electronic device of claim 10 wherein the multi-wire connector is one of a universal serial bus connector and a firewire interface.

16. The electronic device of claim 10 wherein the multi-wire connector is mounted to, and extends from, the housing.

17. The electronic device of claim 10 wherein the electronic device does not include a display.

18. The electronic device of claim 10 wherein the electronic device does not include a user interface for providing user input of instructions or information to the electronic device.

19. The electronic device of claim 10 wherein the component of the sample of the body fluid is one of blood glucose, cholesterol and a blood coagulation parameter.

20. An electronic device for analysis of a body fluid comprising:
a housing defining a first opening therein,
a measuring facility arranged inside the housing and configured to receive a test element therein via the first opening, the measuring facility configured to produce measuring values relating to a sample of the body fluid received on the test element,
at least one electrical circuit arranged inside the housing and configured to process the measuring values to yield analytical data corresponding to a component of the sample of the body fluid, and
a universal serial bus (USB) interface carried by the housing and electrically connected to the at least one electrical circuit,
wherein the measuring facility, the at least one electrical circuit and the USB interface together form a USB device.

21. The electronic device of claim 20 wherein the USB interface is a first USB connector configured to be electrically connected to a second USB connector of one of a USB host and a USB hub.

22. The electronic device of claim 21 wherein the USB host is one of a personal computer, a laptop computer and a notebook computer.

23. The electronic device of claim 20 wherein the USB interface is a wireless USB interface.

24. The electronic device of claim 20 wherein the electronic device does not include a display.

25. The electronic device of claim 20 wherein the electronic device does not include a user interface for providing user input of instructions or information to the electronic device.

26. The electronic device of claim 20 wherein the component of the sample of the body fluid is one of blood glucose, cholesterol and a blood coagulation parameter.

27. The electronic device of claim 20 wherein the measuring facility comprises at least one electrode configured to produce the measuring values based on an electrochemical reaction of the body fluid with the test element.

28. The electronic device of claim 20 wherein the measuring facility comprises an optical detector configured to produce the measuring values based on at least one optical property resulting from a reaction of the body fluid with the test element.

29. The electronic device of claim 20 wherein the USB interface is configured to be electrically connected to a mating USB interface of either of a USB host and a USB hub.

30. An electronic device for analysis of a body fluid comprising:
a housing defining a first opening therein,
a measuring facility arranged inside the housing and configured to receive a test element therein via the first opening, the measuring facility configured to produce measuring values relating to a sample of the body fluid received on the test element,
at least one electrical circuit arranged inside the housing and configured to process the measuring values to yield analytical data corresponding to a component of the sample of the body fluid,
a memory unit arranged inside the housing and having stored therein instructions for operating the electronic device, and
an electrical interface electrically connected to the at least one electrical circuit and configured for communication with an electrical interface of an external electronic device configured to execute the instructions and thereby control the electronic device.

31. The electronic device of claim 30 wherein the electronic device does not include a display.

32. The electronic device of claim 30 wherein the electronic device does not include a user interface for providing user input of instructions or information to the electronic device.

33. The electronic device of claim 30 wherein the component of the sample of the body fluid is one of blood glucose, cholesterol and a blood coagulation parameter.

34. The electronic device of claim 30 wherein the measuring facility comprises at least one electrode configured to produce the measuring values based on an electrochemical reaction of the body fluid with the test element.

35. The electronic device of claim 30 wherein the measuring facility comprises an optical detector configured to produce the measuring values based on at least one optical property resulting from a reaction of the body fluid with the test element.

36. An electronic device for analysis of a body fluid comprising:
a housing defining an opening therein,
a measuring facility arranged inside the housing and configured to receive a test element therein via the opening, the measuring facility configured to produce measuring values relating to a sample of the body fluid received on the test element,
at least one electrical circuit arranged inside the housing and configured to process the measuring values to yield analytical data corresponding to a component of the sample of the body fluid, and
an electrical interface configured to transfer information between the electronic device and an external electronic device,
wherein the electronic device does not include a display.

37. The electronic device of claim 36 wherein the electronic device does not include a user interface for providing user input of instructions or information to the electronic device.

38. The electronic device of claim 36 wherein the component of the sample of the body fluid is one of blood glucose, cholesterol and a blood coagulation parameter.

39. The electronic device of claim 36 wherein the measuring facility comprises at least one electrode configured to produce the measuring values based on an electrochemical reaction of the body fluid with the test element.

40. The electronic device of claim 36 wherein the measuring facility comprises an optical detector configured to produce the measuring values based on at least one optical property resulting from a reaction of the body fluid with the test element.

41. An electronic device for analysis of a body fluid comprising:
a housing defining an opening therein,
a measuring facility arranged inside the housing and configured to receive a test element therein via the opening, the measuring facility configured to produce measuring values relating to a sample of the body fluid received on the test element,
at least one electrical circuit arranged inside the housing and configured to process the measuring values to yield analytical data corresponding to a component of the sample of the body fluid, and
an electrical interface configured to transfer information between the electronic device and an external electronic device,
wherein the electronic device does not include a user interface for providing user input of instructions or information to the electronic device.

42. The electronic device of claim 41 wherein the electronic device does not include display.

43. The electronic device of claim 41 wherein the component of the sample of the body fluid is one of blood glucose, cholesterol and a blood coagulation parameter.

44. The electronic device of claim 41 wherein the measuring facility comprises at least one electrode configured to produce the measuring values based on an electrochemical reaction of the body fluid with the test element.

45. The electronic device of claim 41 wherein the measuring facility comprises an optical detector configured to produce the measuring values based on at least one optical property resulting from a reaction of the body fluid with the test element.

46. A system for analyzing of a body fluid comprising:
a body fluid analysis device comprising a measuring facility configured to receive a test element therein and configured to produce measuring values relating to a sample of the body fluid received on the test element, and at least one electrical circuit configured to process the measuring values to yield analytical data corresponding to a component of the sample of the body fluid,
an electronic device comprising a processor electrically connected to a display unit, and
an electrical interface configured to transfer information between the body fluid analysis device and the electronic device,
wherein the processor is configured to receive the analytical data from the body fluid analysis device and to control the display unit to display the analytical data.

47. The system of claim 46 wherein the electronic device includes a memory having stored therein instructions for operating the body fluid analysis device,
and wherein the processor of the electronic device is configured to execute the instructions stored in the memory to control operation of the body fluid analysis device.

48. The system of claim 46 wherein the body fluid analysis device includes a memory having stored therein instructions for operating the body fluid analysis device,
and wherein the processor of the electronic device is configured to receive the instructions from the memory of the body fluid analysis device and execute the instructions to control operation of the body fluid analysis device.

49. The system of claim 46 wherein the electrical interface comprises:
a first multi-wire connector associated with the body fluid analysis device, and
a second multi-wire connector associated with the electronic device.

50. The system of claim 49 wherein the processor of the electronic device is configured to automatically control operation of the body fluid analysis device, receive the analytical data from the body fluid analysis device and control the display unit to display the analytical data, upon detection of an electrical connection between the first and second multi-wire connectors.

51. The system of claim 46 wherein the electrical interface comprises a universal serial bus (USB) interface.

52. The system of claim 46 wherein the body fluid analysis device does not include a display.

53. The system of claim 46 wherein the body fluid analysis device does not include a user interface for providing user input of instructions or information to the electronic device.

54. The system of claim 46 wherein the component of the sample of the body fluid is one of blood glucose, cholesterol and a blood coagulation parameter.

55. The system of claim 46 wherein the electronic device may be one of a personal computer, a laptop computer and a notebook computer.

56. The system of claim 51 wherein the body fluid analysis device further comprises a USB connector electrically connected to the at least one electrical circuit,
and wherein the body fluid analysis device is a USB device and the electronic device is a USB host.
